(19) United States
(12) Patent Application Publication
(10) Pub. No.: US 2010/0192693 A1
(43) Pub. Date: Aug. 5, 2010

(54) ACOUSTIC TRANSDUCER ASSEMBLY

(76) Inventors: Peter Julian Mudge, Cambridge (GB); Alexander George Haig, Cambridge (GB)

Correspondence Address: MARTIN NOVACK, 16355 VINTAGE OAKS LANE, DELRAY BEACH, FL, 33484, US

(21) Appl. No.: 12/733,227

(22) PCT Filed: Aug. 13, 2008
(86) PCT No.: PCT/GB2008/002737

§ 371 Date: Mar. 23, 2010

(30) Foreign Application Priority Data
Aug. 16, 2007 (GB) 0716047.6

(51) Int. Cl. G01N 29/04; H04R 17/00; H01L 41/053

(52) U.S. Cl. 73/628; 310/334; 310/327

(57) ABSTRACT

An acoustic transducer assembly comprises a bipolar transducer (1) having an active surface with opposite ends that move towards and away from one another in response to an applied electrical fields. An acoustic decoupling material (2) is fixed to one end of the transducer surface, the acoustic decoupling material being such that it substantially prevents acoustic signals passing therethrough and substantially prevents coupling of the transducer's active surface.

The invention relates to an acoustic transducer assembly, for example incorporating a piezoelectric transducer. For the purposes of this specification, “acoustic” shall be defined as being of or relating to sound waves. Acoustic transducers can operate from a sub-hertz frequency range to well into the gigahertz range. The wavelength of the waves produced depends on the medium in which they travel.

A transducer is a device that is activated by one type of energy and converts this into another form of energy. Common examples of transducers are loudspeakers, thermocouples and photocells.

Piezoelectric transducers convert electrical energy into mechanical energy and vice versa. That is, they are deformed under the influence of an electric field and inversely create an electric field under deformation. These transducers have found a wide variety of applications including sonar, record players, medical ultraonography and ultrasound therapy, musical instruments and non-destructive testing (NDT).

Several different materials are used in piezoelectric transducers for their piezoelectric effect including quartz (a piezoelectric crystal), barium titanate (a piezoelectric ceramic) and PZT (lead zirconium titanate—also a piezoelectric ceramic) among others. The type of material used depends on the specific properties required of the transducers. The manner of deformation produced by a piezoelectric material is material specific and depends on the orientation of the piezoelectric polarisation and the orientation and magnitude of the electric field applied. Alternating current produces vibrating deformations and vice versa. This allows the construction of electromechanical transducers for creating and sensing vibrations. When a transducer of this kind is placed in contact with a body, the vibrating capabilities allow it to transmit and receive acoustic signals. These characteristics lend themselves to the use of electromechanical transducers for ultrasound applications. In many of these applications, the transducers are required to vibrate in the direction normal to the surface of a body. However, emerging technologies, such as long-range ultrasonics, require transducers that vibrate in parallel with the surface. This movement causes shear stress variations at the surface and allows the generation of mechanical waves parallel to a material surface, which may be used to transmit specific types of guided waves. Useful wave modes in plates and pipes, such as transverse, compression and flexural waves, have significant displacements parallel with the plate or pipe surfaces. In the case of pipes, this can obviously be along the circumference or long axis. Inversely, the transducers can detect passing guided waves by sensing displacement parallel to the surface. These are of particular use in the field of long-range ultrasonic testing, where direct access to the whole of a body (such as a buried pipe) is not always possible—guided waves may be directed along the inaccessible length of a body from an accessible area. This is in comparison to other forms of ultrasonic testing where compression transducers are used, which vibrate at a normal to the surface; examination is generally only possible of the area directly under the probe.

A common way to create useful guided wave modes is to use a shearing monopolar piezoelectric element. A shearing element is caused to deform such that one surface moves in a parallel and opposite direction to the surface on the far side of the element. Either of these surfaces is then used as the contact surface, which will be shifted parallel to the contact surface.

Monopolar transducers are used because the displacement at any point on the contact surface is equal, meaning that a single signal is transmitted. If the surface area in contact with the body is also relatively small (compared to the wavelength of the acoustic signals), then the device may be considered as a point source transmitter and receiver. Among several advantages, point source devices produce signals with reduced levels of destructive interference.

Bipolar transducers are also available. Apart from their polar nature, the properties of monopolar and bipolar transducers are very similar. It has been found that piezoelectric transducers consisting of types other than thick, single element, shearing transducers may be used to generate shear stress variations, such as the Macro Fibre Composite (MFC) actuators, as described in U.S. Pat. No. 6,629,341. Macro Fibre Composites are a type of Piezoelectric Active Fibre Composite. These devices make use of interdigitated electrodes that give a number of short-range electric fields, which yield a higher intensity than a single larger one. They also benefit from the highly efficient d₃₃ type polarisation where the electric field is in plane with the displacement along the 3-axis. Housed within each of these transducers are a number of long narrow elements that extend or contract under an electric field, rather than shear. In these the deformation will act lengthways, resulting in a cumulative displacement, i.e. the ends of the elements will be moving a great deal in comparison to the centres.

These MFC actuators may be used as transducers for applications that require guided waves generated on a surface parallel to the wave vector. However, as the elements either extend or contract when placed on a surface the vibration at each end of the elements will be working completely out of phase. Where the device must act as a point source (and in a monopolar fashion) these actuators cannot be used. In particular, it is very difficult to generate sh-waves (transverse waves with horizontal particle displacement) efficiently in plates with bipolar transducers because the outputs of the poles interact destructively—each pole of a bipolar transducer is the inverse of the other; the signal amplitude of one pole is equal and opposite of the other. Torsional waves travel along tubular structures and are based on a circumferential twisting displacement. This mode is analogous to sh-waves in plates and cannot be generated in an isolated fashion (without generation of other interfering modes) with a conventional bipolar transmitter. Torsional waves are very useful for long-range, low frequency ultrasonic inspection of items such as pipes.

An existing method of isolating one pole of a bipolar transducer is to apply a load on one part of a transducer while having the other pull back slightly away from the body. This method is known in the art for use with transducer types such as those described in WO96/12951, but has proven to be unreliable. Whilst a similar method can be applied to bipolar transducers such as MFCs, it has proven equally unreliable. Initial experimentation has shown that whilst a shear wave can be produced with an MFC loaded on one side, there are unwanted modes and high noise. As the acoustic energy developed in the unloaded side does not transmit through the active surface, it may cause ringing in the housing and the opposing pole. Applying a mechanical load to some areas of a transducer, whilst leaving others free, poses a practical challenge and may require a complex loading mechanism. In accordance with the present invention, an acoustic transducer assembly comprises a bipolar transducer having an active surface with opposite ends that move towards and away from one another in response to an applied electrical field; and an acoustic decoupling material fixed to one end of the transducer surface, the acoustic decoupling material being such that it substantially prevents acoustic signals passing therethrough and substantially prevents coupling of one end of the transducer's active surface.

The acoustic decoupling material can act by presenting a poor acoustic impedance match with both the transducer and a surface to which the transducer is mounted and/or by substantially limiting acoustic signal from this end passing therethrough by attenuating the signal.

In contrast to the prior art, instead of trying to hold part of the bipolar transducer away from the workpiece, the assembly provides an acoustic decoupling material fixed to one end of the transducer surface so as to absorb, reflect and/or attenuate the passage of acoustic signals. This enables the advantages of a bipolar transducer to be obtained but without the disadvantages mentioned above.

In particular, the invention provides the ability to apply an even load so that a simple loading mechanism is possible, such as a clamp or air bladder.

In a typical example, one part of the contact surface of the piezoelectric element is laminated with an acoustic coupling material (preferably one that has limited attenuative properties and forms a good acoustic couple between the element and a target material) while another part is laminated with the acoustic decoupling material with a poor acoustic impedance match and/or highly attenuative properties. The material having limited attenuative properties allows transmission of acoustic signals from one region of the piezoelectric element to the body in the case where the transducer is acting as a transmitter and reception of acoustic signals when the transducer is acting as a receiver, while the acoustic decoupling material prevents substantial transmission of acoustic signals from, or receiving of acoustic signals by, the other region of the element. In this fashion one pole of the bipolar device may effectively be isolated. If the contact area is small enough in comparison to the wavelength of the displacement, then the element may also be considered as a point source. Bipolar actuators, which may otherwise not have been useful in such a manner, may be used in applications that require monopolar acoustic transducers.

Typical materials that can be used for the portion of the composite facing having good acoustic coupling properties include steel, aluminium or a suitable impedance matching material known in the art, such as alumina or even a polymer material, such as described in WO2005057205. These can take the form of laminas, shims or other suitable shapes. As an alternative to providing a material with good acoustic coupling properties, a part of the piezoelectric device could be in direct contact with the body and effectively left bare, although use of a shim provides physical protection for the transducer.

Typical materials that can be used for the portion of the composite facing having acoustic decoupling properties include latex, polyurethane, polyethylene or any other effective damping material. Materials with a particularly low density and shear modulus are generally suitable. The required thickness of materials used for the composite facing is dependent on the impedance matching and attenuating properties of the materials and should generally be kept to a minimum to make the transmitting surface as effective as possible.

The piezoelectric device may be joined to the surface of the body or workpiece by a thin layer of adhesive or it can be mechanically loaded. The mechanical load can be provided by a suitable clamp, typically using mechanical, pneumatic or hydraulic pressure. The lamina layers can be fixed by the edges or/and bonded to the surface of the piezoelectric element in some manner, for example by using temporary adhesives (adhesive tapes, EVA/PA/hot melt adhesives, glues, putties &c.), permanent adhesives (epoxies, acrylics, polyamides, cyanoacrylates) or mechanical fixings. The piezoelectric device may be incorporated into an assembly for securing, protecting and positioning a single device, and/or into a larger assembly consisting of multiple devices (such as a ring-like belt) for securing to a body, such as a pipe, plate, rail, rod or any other waveguide.

This transducer type will have uses throughout ultrasonic testing, especially in long-range ultrasonics. This invention is particularly useful for generating and receiving guided waves whereby waves are excited on a surface parallel to the direction of transmission. This widens the applicability of bipolar transducers for use in many new areas of ultrasonic testing.

Typical acoustic frequencies used for guided waves in long-range ultrasonic testing generally fall within the kilohertz (kHz) range, typically 1 kHz to 500 kHz (when inspecting steel pipes, for example, a frequency range of 20 to 100 kHz may be used), although devices modified according to the invention would have applications in any achievable frequency range. They may be used in mid and high frequency ultrasonic testing methods, such as phased array testing. They also have the potential to be used for materials characterisation, medical scanning, flow meters and a wide range of applications that use piezoelectric transducers.

The invention allows the use of a wider range of piezoelectric devices for many acoustic applications.

For many of these applications, including guided wave inspection, the wider range of transducers that the invention allows to be used includes transducers that offer:

High sensitivity due to multiple in-plane interdigitated electrodes

High signal to noise ratio

High level of robustness

High flexibility and conformance—can be used on curved surfaces

Low cost relative to prior-art monopolar devices

Low weight relative to prior-art monopolar devices

Invariant performance and high reliability

Some examples of transducer assemblies according to the invention and methods for their use will now be described and contrasted with prior art methods with reference to the accompanying drawings, in which:

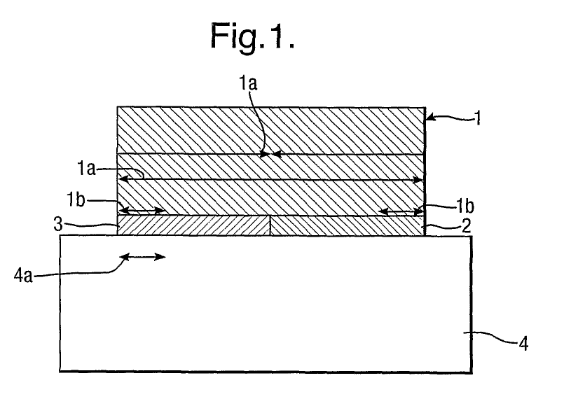

FIG. 1 is a side view of a transducer assembly according to an aspect of the invention;

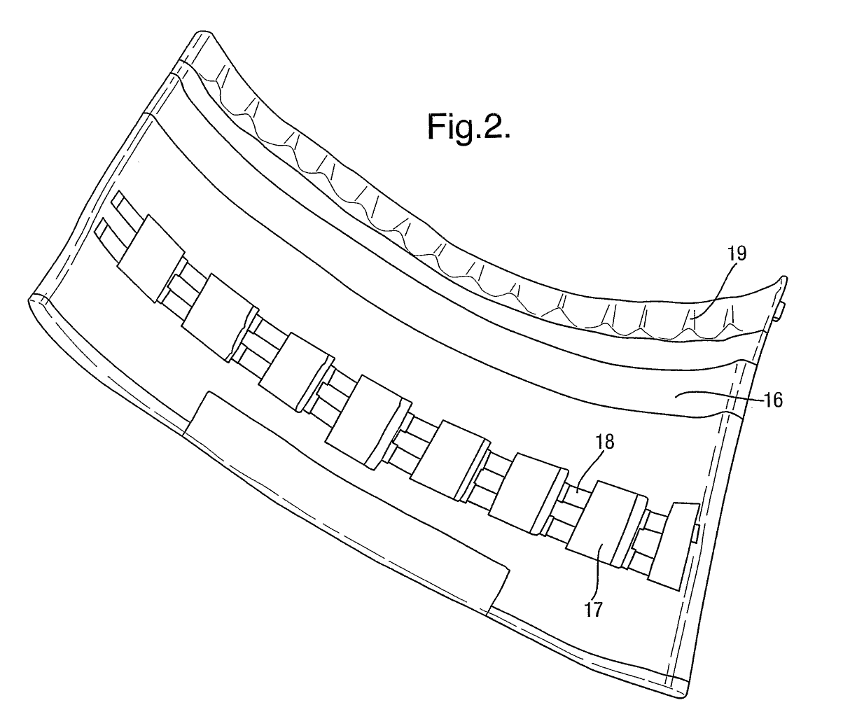

FIG. 2 shows a housing to which multiple assemblies are secured;

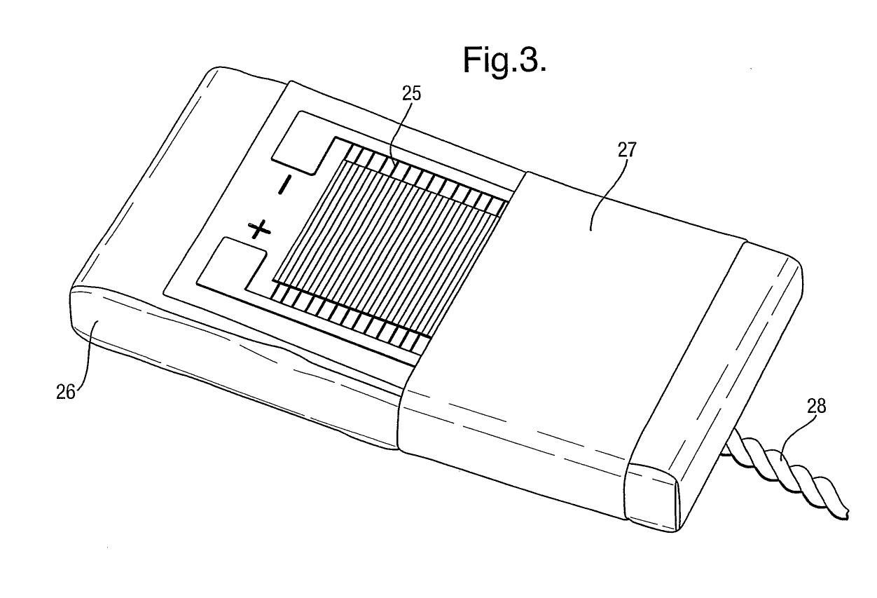

FIG. 3 shows another example of a transducer assembly according to the invention;

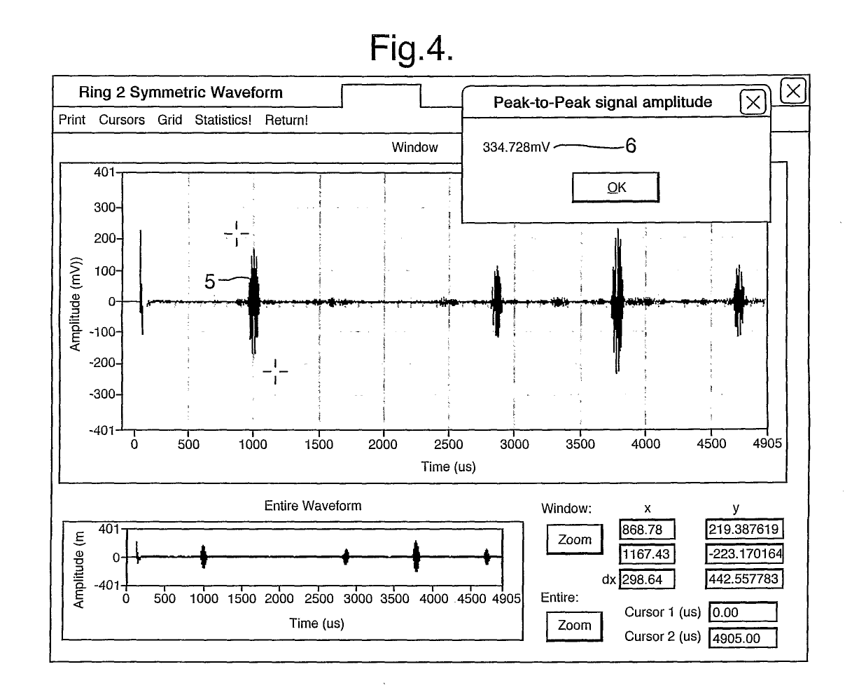

FIG. 4 shows typical waveform results from using a device according to the invention;

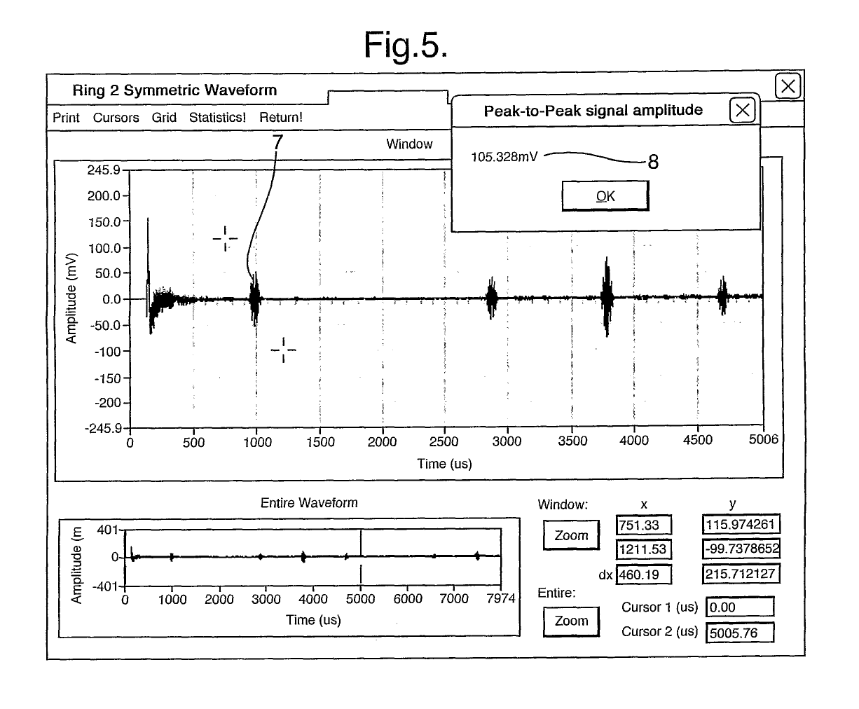

FIG. 5 shows typical waveform results from using a traditional shear type transducer device;

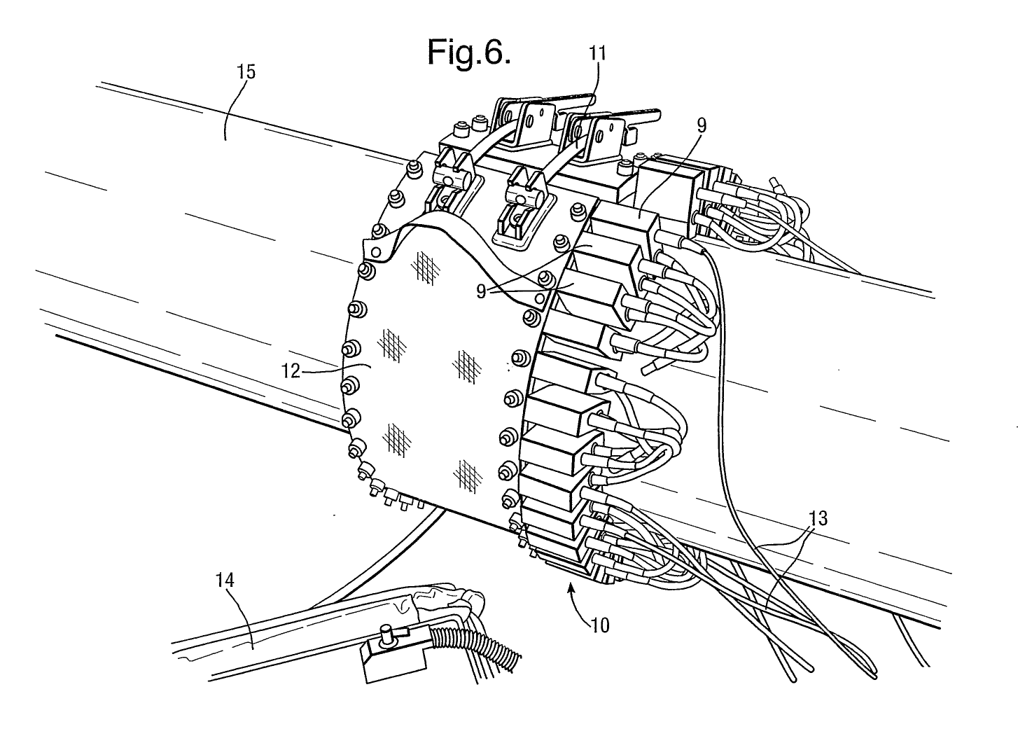

FIG. 6 is a perspective view of a typical prior-art array for long-range ultrasonic testing; and,

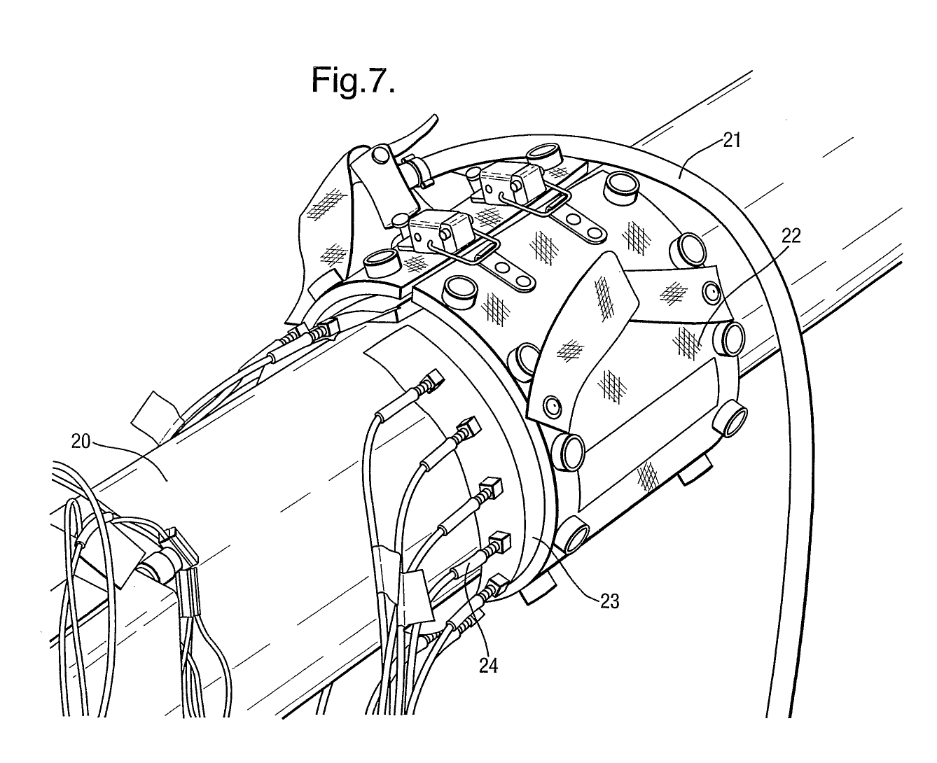

FIG. 7 is a perspective view of an array containing devices according to the invention.

FIG. 1 illustrates a device according to an example of the invention. In this case, a bipolar piezoelectric element or transducer 1 is caused to deform by action of an electric field which results in a displacement as indicated by the arrows 1a. These arrows indicate the shape change of the element under an alternating electric signal. This leads to a relatively large cumulative displacement towards the ends of the element as indicated by the arrows 1b which show the right hand side being completely out of phase with the left. This results in the element acting in a bipolar fashion. The acoustic decoupling material 2 prevents the transmission of signal to a body or workpiece 4, while the material 3 forms a good acoustic couple between the transducer and body, and allows transmission of a single coherent acoustic signal, indicated by the arrow 4a. In effect, the element is only transmitting one pole of its bipolar displacement, therefore acting in a monopolar fashion.

FIG. 2 illustrates a sensor array constructed using a number of assemblies according to the invention. A closed cell foam backing 16 provides a platform for several MFC transducers, the faces of which are covered on one half by layers of acoustic decoupling latex 17 while the other halves of the faces 18 are not covered and left to make direct contact with the surface. The latex is less than 0.4 mm thick and, as the transducers are flexible, the bare side 18 is easily pushed down onto the surface. A thin plastic layer (on the back of the housing and not seen here) holds connectors and wires in place, which can be discerned under the durable adhesive tape 19 that holds the various components in place against the foam back and plastic layers. The arrangement shown in this figure would typically be attached to a waveguide for testing, as shown in FIG. 7.

FIG. 3 shows an MFC transducer modified in accordance with another example of the present invention. The transducer 25 is attached to a supportive foam backing 26. Acoustic decoupling latex material 27 prevents acoustic communication with a predetermined portion of the transducer. The remaining face of the transducer is uncovered to allow acoustic communication. Control and monitoring signals are transferred along the connection 28. The constituent parts are held together using a suitable adhesive tape.

FIGS. 4 and 5 show screen captures taken from computer control and monitoring apparatus attached to a device according to the invention and a prior-art monopolar device, respectively. The prior-art monopolar device is known to generate and receive torsional waves. The device according to the invention, when placed under the same conditions, produces very similar signals with a notable increase in amplitude. This is an indication that the inventive device is generating and receiving torsional waves and, as such, the bipolar transducers used are effectively acting in a monopolar fashion. As can be seen from visual inspection of signal amplitudes 5 and 7 and peak-to-peak measurements 6 and 8, the inventive device displays around three times the amplitude of the prior-art device. Measuring the time of flight of the first received echo from a known distance confirms the speed to be that of a torsional wave.

FIG. 6 is a perspective view of a prior-art ring array arrangement used for long-range ultrasonic testing attached to a test pipe 15. A plurality of transducer assemblies 9 are arranged and secured in a ring array 10, fixed using a mechanical clamp 11 and carbon fibre composite securing collar 12. Control and monitoring signals are transmitted through cables 13 to a control unit 14.

FIG. 7 is a perspective view of a ring array arrangement consisting of devices according to the invention, arranged in the manner shown in FIG. 2, to be used for long-range ultrasonic testing attached to a test pipe 20. A compressed air supply 21 provides pressure to an inflatable bladder contained in a carbon fibre composite securing collar 22. The air pressure is used to load the back of the sensor housing 23 and hold it against the test pipe. Control and monitoring signals are transmitted through cables 24 to a control unit (not shown).

### Embodiment of Invention/Worked Example

We have applied this concept to a type of MFC bipolar actuator and found that it could generate and sense unidirectional shear stress.

As mentioned, the long-range, low frequency ultrasonic inspection of pipes is one application in which the invention will find use. Waves of specific and selected mode types are generated in a pipe, such that the wave travels along the axis of the Pipe.

Existing MFC piezoelectric actuators modified in accordance with the invention were used in a ring array arrangement on a pipe in an attempt to generate a torsional wave. Torsional waves vibrate in a twisting action circumferentially and can only be created with a monopolar array.

A ring of transducers were placed at equal intervals around the circumference of a pipe. These were constructed using bipolar MFCs adapted to have one half of their contact surface masked to decouple one of the two poles.

The transducer faces consisted of a bare region over one half of each face and three layers of 0.15 mm thick latex, fixed with adhesive tape, on the other. The addition of further layers of latex enhanced the decoupling effect. A single thicker layer of latex could be used in place of the multiple layers, and a suitable adhesive compound or mechanical fixing means could be used in place of adhesive tape.

The transducers were aligned such that displacement of each was acting clockwise around the pipe circumference.

A transmit and receive test confirmed that torsional waves were being created. If both poles of the MFCs were acting, it would not be possible to generate torsional waves.

A comparison test between this tool and a tool made up with normal shear type transducers showed that the invention exhibited increased sensitivity. Comparing the results of a pulse echo test showed that the MFC actuator, as modified according to the invention, received a signal with three times the amplitude of a normal shear type transducer. This is because the MFC transducers are much more sensitive than the conventional rigid shear transducers (even with a masking layer). Since this is a pulse echo system, the improvement in sensitivity applies to transmission and reception.

The particular configuration described above is ideal for use in detecting defects in pipes. The increased amplitude would likely result in an increased range during testing of pipes.

1. An acoustic transducer assembly comprising a bipolar transducer having an active surface with opposite ends that move towards and away from one another in response to an applied electrical field; and an acoustic decoupling material fixed to one end of the transducer surface, the acoustic decoupling material being such that it substantially prevents acoustic signals passing therethrough and substantially prevents coupling of the transducer's active surface.

2. A transistor assembly according to claim 1, further comprising an acoustic coupling material fixed to the other end of the active surface of the transducer, the acoustic coupling material allowing acoustic signals to pass therethrough substantially without attenuation and also coupling acoustic signals of the other end of the active surface of the transducer.

3. A transducer assembly according to claim 2, wherein the active surface of the transducer is fully covered by the acoustic decoupling material and the acoustic coupling material.

4. A transducer assembly according to claim 2, wherein the acoustic coupling material comprises steel, aluminum or other impedance matching material such as alumina.

5. A transducer assembly according to claim 2, wherein the acoustic coupling material is laminated to the active surface.

6. A transducer assembly according to claim 2, wherein the acoustic coupling material is fixed at its edges to the active surface.

7. A transducer assembly according to claim 6, wherein the acoustic coupling material is bonded to the active surface.

8. A transducer assembly according to claim 1, wherein the acoustic coupling material is bonded using a temporary adhesive, such as adhesive tape or a hot melt adhesive.

9. A transducer assembly according to claim 2, wherein the acoustic coupling material is a multi-layer laminate.

10. A transducer assembly according to claim 1, wherein the acoustic decoupling material comprises one of latex, polyethylene and polyurethane.

11. A transducer assembly according to claim 1, wherein the acoustic decoupling material is fixed at its edges to the active surface.

12. A transducer assembly according to claim 11, wherein the acoustic decoupling material is bonded to the active surface of the transducer.

13. A transducer assembly according to claim 12, wherein the acoustic decoupling material is bonded using a temporary adhesive, such as adhesive tape or a hot melt adhesive.

14. A transducer assembly according to claim 1, wherein the acoustic decoupling material is a multi-layer laminate.

15. A transducer assembly according to claim 1, wherein the bipolar transducer is a piezoelectric transducer.

16. A transducer assembly according to claim 15, wherein the bipolar transducer is made of Piezoelectric Active Fibre Composite.

17. A transducer assembly according to claim 1, further including a support to which the bipolar transducer is attached.

18. A transducer assembly according to claim 17, wherein the support is a belt adapted to secure the transducer to a workpiece such that acoustic signals and displacements can be transferred to and from the bipolar transducer via said other end of the active surface of the transducer.

19. A transducer assembly according to claim 17, wherein the support includes a clamp for clamping the transducer to a workpiece.

20. A transducer assembly according to claim 19, wherein the acoustic decoupling material and the acoustic coupling material, if provided, are adapted to be sandwiched and held in position between the active surface of the transducer and a workpiece by the clamp.

21. A method of testing the integrity of a workpiece, the method comprising mounting one or more acoustic transducer assemblies to the workpiece; causing the or each transducer assembly to transmit acoustic signals along the workpiece; and detecting reflected acoustic signals from the workpiece using the same or another acoustic transducer assembly, said one or more acoustic transducer assembly comprising a bipolar transducer having an active surface with opposite ends that move towards and away from one another in response to an applied electrical field; and an acoustic decoupling material fixed to one end of the transducer surface, the acoustic decoupling material being such that it substantially prevents acoustic signals passing therethrough and substantially prevents coupling of the transducer's active surface.
